(19) United States
(12) Patent Application Publication
(10) Pub. No.: US 2024/0234393 A1
(43) Pub. Date: Jul. 11, 2024

(54) TRANSPARENT LED DISPLAY DEVICE INTEGRATED WITH SMPS AND MANUFACTURING METHOD THEREOF

(71) Applicant: LEORIA Inc., Hwaseong-si, Gyeonggi-do (KR)

(72) Inventor: Jun Cheol KO, Hwaseong-si, Gyeonggi-do (KR)

(73) Assignee: LEORIA Inc., Hwaseong-si, Gyeonggi-do (KR)

(21) Appl. No.: 17/928,286

(22) PCT Filed: Nov. 3, 2022
(86) PCT No.: PCT/KR2022/017101

§ 371 Date: Nov. 29, 2022

(30) Foreign Application Priority Data
Apr. 25, 2022 (KR) 10-2022-0050808

(51) Int. Cl. H01L 25/16; H05K 3/00; H05K 3/06; H05K 3/24; H05K 3/36

(52) U.S. Cl. CPC H01L 25/167; H01L 25/165; H05K 3/005; H05K 3/06; H05K 3/244; H05K 3/363

(57) ABSTRACT

A method for manufacturing a transparent LED display device includes forming a line of a grid-shaped metal mesh pattern on a first surface of both surfaces of a transparent heat-resistant optical PET by using a wet etching method on a transparent heat-resistant optical PET film, punching a hole in the transparent heat-resistant optical PET film and soldering a line of a controller PCB placed on a second surface of both the surfaces of the transparent heat-resistant optical PET and the line of the metal mesh pattern on the first surface to electrically connect the controller PCB to the line of the metal mesh pattern, mounting color LEDs on the first surface of the transparent heat-resistant optical PET film, and integrally coupling the SMPS to the transparent heat-resistant optical PET film.

### TECHNICAL FIELD

The present invention relates to a transparent LED display device and a method for manufacturing the same.

### BACKGROUND ART

LEDs (light emitting diodes) are being used as billboards or electronic billboards in various places such as department stores, shops, and shopping malls. Particularly, a transparent LED display is installed on an outer wall or window of a building and is used to display advertisements or various information.

In a polyester (PET) film-based transparent LED display, a circuit line is disposed on a PET film, color LEDs are disposed, and current is applied to the color LEDs so that the color LEDs emit light. In order to improve transparency and visibility of the transparent LED display, it is necessary to deteriorate recognition of the circuit line and to dispose the color LEDs more densely.

In addition, the transparent LED display is often installed in a large size on an outer wall or window of a building, and a separate power supply is required to supply power to the transparent LED display. However, aesthetics and visibility of the transparent LED display may be deteriorated due to the power supply, and a separate bezel for placing the power supply exists on the transparent LED display to defame meaning as the transparent LED display and deteriorate spatiality.

### DISCLOSURE OF THE INVENTION

### Technical Problem

A circuit line having a metal mesh shape may be formed on a PET film to provide a film for a transparent LED display device. In addition, a power supply may be integrated with a transparent LED display device to realize a constructive and large display.

The technical object to be achieved by this embodiment is not limited to the above-mentioned technical object, and other technical objects may be deduced from the following embodiments.

### Technical Solution

A circuit line having a metal mesh shape may be formed on only a PET film to provide a film for a transparent LED display device. In addition, a PCB controller may be attached to a rear surface (a surface opposite to a surface on which the metal mesh-shaped circuit line is formed) of the PET film, and the PCB controller and the metal mesh-shaped circuit line may be connected to each other through soldering. Additionally, a power supply may be integrated with a transparent LED display device to realize a constructive and large display.

### Advantageous Effects

Since the line having the metal mesh pattern is formed on only one surface of the PET film, there may be much more advantageous in terms of the manufacturing cost when compared that the metal mesh-shaped line is formed on each of both the surfaces, and since the controller PCB is disposed on the rear surface, there may be advantageous in that the controller is not visible in the direction in which the people looks at the display device. The power supply may be integrated with the transparent LED display device to realize the constructive and large display. In general, the plurality of unit PET film (referred to as the cell)-based transparent LED displays may be connected to each other to realize the large digital signage screen. Here, since the power supply is disposed for each unit PET film, the supplying of the power to each of the cells may be smooth compared to supply the power to each of cell of the one large power supply, thereby improving the luminance of the display.

### BRIEF DESCRIPTION OF THE DRAWINGS

FIG. 1 is a flowchart illustrating a method for manufacturing a transparent LED display device according to an embodiment.

FIG. 2 is a view illustrating a sputtering method according to an embodiment.

FIG. 3 is a view illustrating a film for a transparent LED display device on which a first copper layer and a second copper layer are disposed according to an embodiment.

FIG. 4 is a view illustrating a film for a transparent LED display device on which a copper layer is disposed according to an embodiment.

FIG. 5 is a view illustrating a portion of a cross-section of the transparent LED display device according to an embodiment.

FIG. 6 is a view illustrating a state in which a controller PCB and a transparent heat-resistant optical PET film are connected to each other according to an embodiment.

FIG. 7 is a view illustrating holes of a fabric on which a metal mesh pattern is formed according to an embodiment.

FIGS. 8 and 9 are views illustrating a state in which the controller PCB is coupled to the film for the transparent LED display device according to an embodiment.

FIG. 10 is a view illustrating a state in which a housing including an SMPS is coupled to the film for the transparent LED display device according to an embodiment.

FIG. 11 is a view illustrating a portion of a cross-section of the film for the transparent LED display device according to an embodiment.

FIG. 12 is a view illustrating a portion of a cross-section of the transparent LED display device manufactured by the disclosed manufacturing method according to an embodiment.

FIG. 13a is a view illustrating a state in which the SMPS is embedded in the housing (under a lid), and FIG. 13b is a view illustrating a state in which the lid is seen in a state in which the housing of FIG. 13a is turned upside down.

FIG. 14a is a view illustrating a first surface of a front surface or both surfaces of the transparent heat-resistant optical PET film according to an embodiment, and FIG. 14b is a view illustrating a second surface of a rear surface or both the surfaces of the transparent heat-resistant optical PET film according to an embodiment.

FIG. 15 is a view illustrating the transparent LED display device according to an embodiment.

### BEST MODE FOR CARRYING OUT THE INVENTION

A method for manufacturing a transparent LED display device includes: forming a copper layer on a transparent heat-resistant optical PET film; forming a line having a grid-shaped metal mesh pattern on a first surface of both surfaces of a transparent heat-resistant optical PET by using a wet etching method on the transparent heat-resistant optical PET film; plating tin on the line; punching a hole in the transparent heat-resistant optical PET film and soldering a line of a controller PCB placed on a second surface of both the surfaces of the transparent heat-resistant optical PET and the line of the metal mesh pattern on the first surface to electrically connect the controller PCB to the line of the metal mesh pattern; mounting color LEDs on the first surface of the transparent heat-resistant optical PET film; connecting a power socket on the controller PCB to an SMPS through a power line and assembling a housing, in which the SMPS is embedded, with the second surface of the transparent heat-resistant optical PET film to integrally couple the SMPS to the transparent heat-resistant optical PET film; and applying a resin to the first surface of the transparent heat-resistant optical PET film, wherein the forming of the copper layer includes forming a first copper layer on the transparent heat-resistant optical PET film by applying the sputtering method and forming a second copper layer on the first copper layer by applying an electroless chemical copper plating process, wherein each of the color LEDs has a pitch greater than 5 μm and less than 50 μm, and the line of the metal mesh pattern has a width greater than 5 μm or less than 50 μm.

The first copper layer may have a height of 1 μm, and the second copper layer may have a height of 35 μm.

The method may further include injecting water to a surface, on which the transparent heat-resistant optical PET film is attached, or the resin to attach the transparent heat-resistant optical PET film to the surface.

A transparent LED display device manufactured by the method for manufacturing the transparent heat-resistant optical PET film may be disclosed.

A transparent LED display device being attachable to a wall or surface includes: a copper line formed into a shape of a metal mesh pattern on a transparent heat-resistant optical PET film; color LEDs mounted on a first surface of both surfaces of the transparent heat-resistant optical PET film; and a resin applied to the first surface, wherein water is applied to the resin so as to be attached to the wall or surface.

The transparent LED display device may further include: a controller PCB configured to control an on/off state of the color LEDs or applied current; and a housing comprising an SMPS configured to supply power to the transparent LED display device, wherein a line of a controller PCB placed on a second surface of both the surfaces of the transparent heat-resistant optical PET film and a line of the metal mesh pattern on the first surface may be soldered through a hole punched in the transparent heat-resistant optical PET film to electrically connect the controller PCB to the line of the metal mesh pattern, and the housing may be integrally coupled to the transparent heat-resistant optical PET film so that an SMPS provided in the housing and a power socket on the transparent heat-resistant optical PET film are connected to each other through a power line.

### MODE FOR CARRYING OUT THE INVENTION

Hereinafter, some embodiments will be described clearly and in detail with reference to the accompanying drawings so that those of ordinary skill in the art to which the present invention pertains (hereinafter, those skilled in the art) can easily practice the present invention.

Hereinafter, a transparent LED display device may be a flexible transparent LED display device. The transparent LED display device is configured to implement a large billboard or a digital signage system. Here, the digital signage system is implemented by arranging several transparent LED display devices, and one transparent LED display device may be referred to as a cell.

Hereinafter, a transparent heat-resistant optical PET film may be replaced with a general PET film.

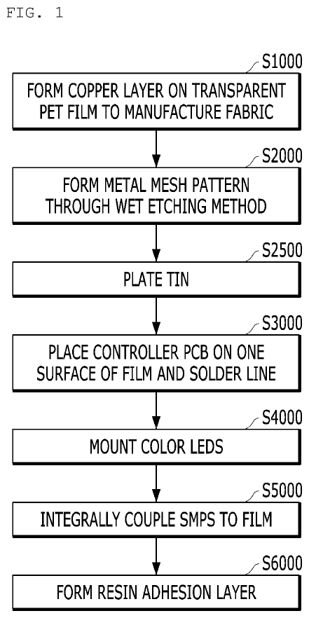

FIG. 1 is a view illustrating a method for manufacturing a transparent LED display device according to an embodiment.

In operation S1000, a fabric may be manufactured by forming a copper layer on a transparent heat-resistant optical PET film.

When the copper layer is formed by attaching a commercially available 18 μm copper foil material to the transparent heat-resistant optical PET film using an adhesive liquid, a flow of current is not smooth due to increasing resistance. The more a height of the copper layer decreases, the more sheet resistance increases. As the sheet resistance increases, supplying of the current is not smooth when the transparent LED display device is driven, and thus, luminance of the transparent LED display device is lowered, and the number of LEDs per unit area of the transparent LED display device may also be reduced.

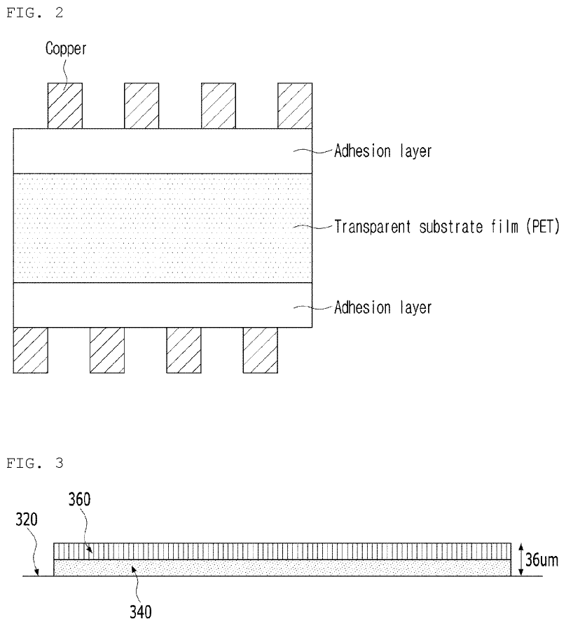

According to an embodiment, the copper layer may be formed to have a height of about 36 μm on an upper end (one surface of both surfaces) of the transparent heat-resistant optical PET having a thickness of 100 μm. Referring to FIG. 2, according to an embodiment, an adhesion layer may be disposed on the upper end of the PET, and the copper layer may be disposed on the adhesion layer.

According to an embodiment, a sputtering method may be applied to deposit copper, thereby forming a first copper layer (CU Layer) on the upper end of the transparent heat-resistant optical PET film, and an electroless copper plating process may be applied to additionally form a second copper layer on the first copper layer. The sputtering method refers to a technique for forming a thin film on a substrate by allowing ionized gas atoms to collide with a deposition target material.

For example, the copper layer 340 (Cu Layer) may be primarily formed at a thickness of 1 μm on the transparent heat-resistant optical PET 320 through the sputtering method, and the copper layer 360 may be secondarily formed at a thickness of 35 μm on the copper layer 340 through the electroless chemical copper plating process to form a copper layer having total thickness of 36 μm.

For example, referring to FIG. 3, the copper layer 340 (Cu Layer) may be primarily formed at a thickness of 1 μm to 18 μm on the transparent heat-resistant optical PET 320 through the sputtering method, and the copper layer 360 may be secondarily formed at a thickness of 18 μm on the copper layer 340 through the electroless chemical copper plating process to form a copper layer having total thickness of 36 μm.

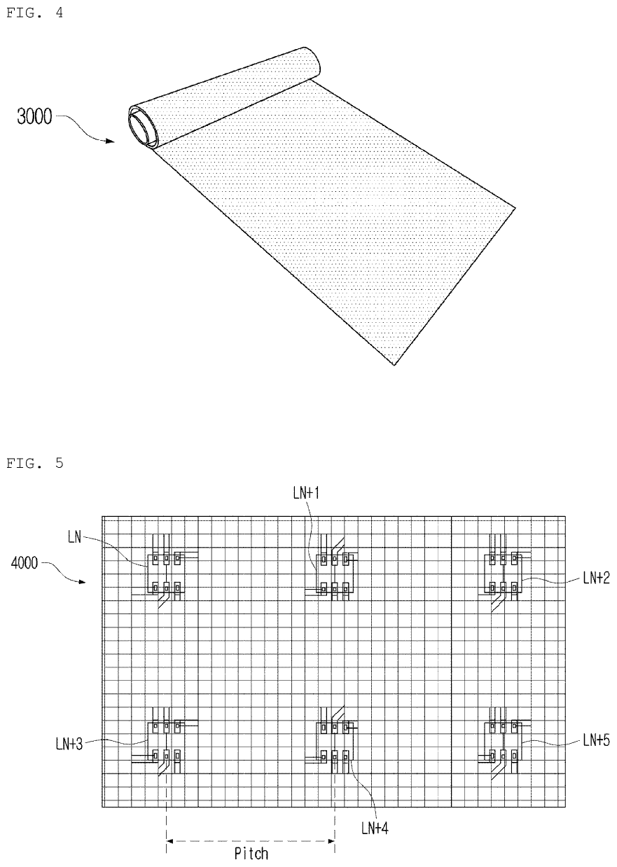

The reason in which the first copper layer is formed first through the sputtering method is to increase in adhesive force between the transparent heat-resistant optical PET film and the copper layer so as to form a more strong grid-shaped metal mash pattern when forming a copper foil circuit line, and this is because, when the copper layer is formed only by the electroless chemical copper plating process, the adhesion between the transparent heat-resistant optical PET film and the copper layer is very low, and thus, the copper layer formed on the film is easily peeled off. However, a very long manufacturing process time is required to form the copper layer by the sputtering method. Therefore, a thin copper layer may be formed first by the sputtering method, and then, a copper layer having a remaining thickness may be formed by the electroless chemical copper plating process. For example, a copper layer having a thickness 1 μm may be formed through the sputtering method, and a copper layer having a thickness of 35 μm may be additionally formed through the electroless chemical copper plating process. FIG. 4 is a view illustrating a transparent heat-resistant PET film 3000 on which the copper layer is formed according to an embodiment.

Referring back to FIG. 1, in operation S2000, a metal mesh pattern line may be formed on the transparent heat-resistant optical PET film manufactured in operation S1000 by using a wet etching method. The metal mesh pattern line may be formed only on one surface of the transparent heat-resistant optical PET film. According to an embodiment, the metal mesh pattern may be a copper wire formed in the form of a grid pattern. The line may have a width of about 5 μm to about 50 μm. The grid-shaped metal mesh pattern may be formed to have a line width less than that of the line pattern to improve visibility and transparency in realizing of the transparent LED display.

In operation S2500, tin may be plated on the transparent heat-resistant optical PET film on which the metal mesh pattern line is formed in operation S2000. The tin plating may prevent copper from being discolorated or oxidized, and when the color LED is transferred onto the PET film to perform SMT, the tin plating may react with low-temperature solder in a high-temperature process to provide higher sealing force.

In operation S3000, a controller PCB (Printed Circuit Board) may be mounted on the transparent heat-resistant optical PET film on which the line having the metal mesh pattern is formed in operation S2000.

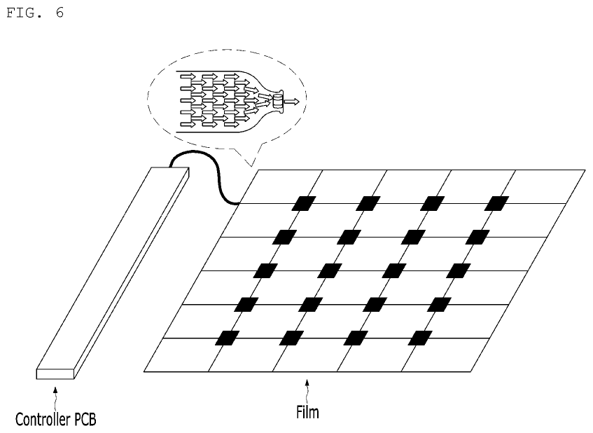

A sense of unity may be realized by mounting the controller PCB on the transparent heat-resistant optical PET film compared that an external controller PCB controls an on/off state of the color LEDs of the display device film, or applied current is controlled through a ZIF connector. FIG. 6 illustrates a state in which the controller PCB disposed outside the transparent heat-resistant optical PET film is connected to a connector (not shown) mounted on the film through a harness cable to control the on/off state of the color LEDs of the film for the display device or the applied current. In such an embodiment, since power and/or data are transmitted through the harness cable, a bottleneck phenomenon may occur to cause problems in smooth flow of the current and an obstacle in implementing of high brightness and large-sized display (e.g., digital signage).

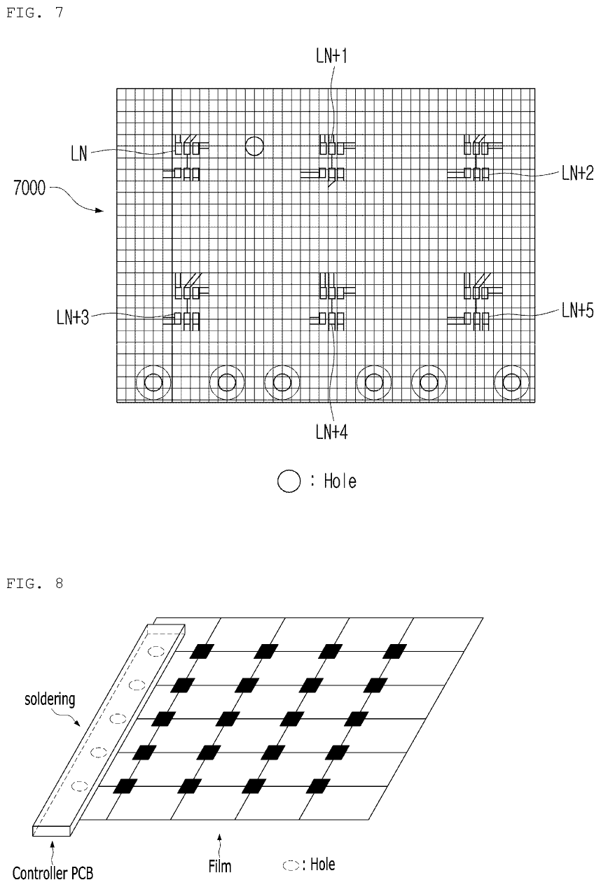

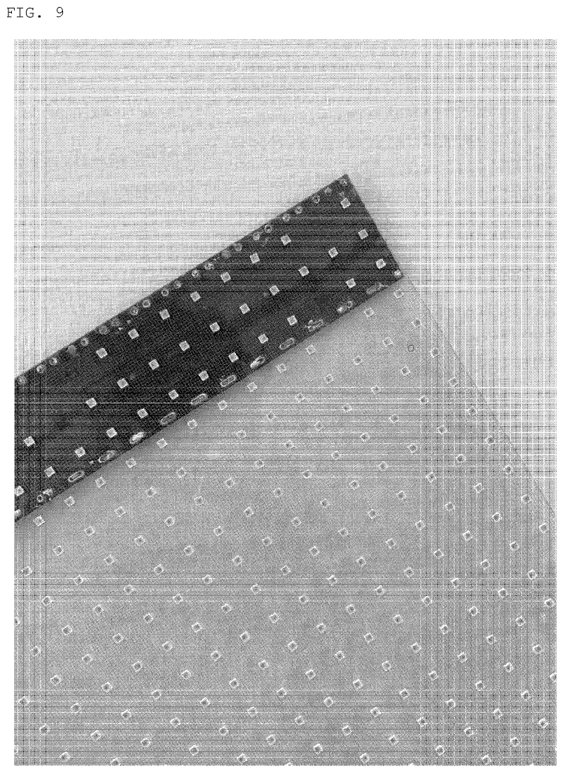

According to an embodiment, the lines of the grid-shaped metal mesh pattern formed on the first surface of both the surfaces of the transparent heat-resistant optical PET film and the lines of the controller PCB placed on the second surface (an opposite surface of the first surface) of both the surfaces of the transparent heat-resistant optical PET film may be soldered on the transparent heat-resistant optical PET film, on which the metal mesh pattern line is formed, by passing through the plurality of holes, and thus, the controller PCB and the line of the metal mesh pattern may be electrically connected to each other. FIG. 7 is a view illustrating the holes of the fabric on which the metal mesh pattern is formed according to an embodiment, and FIG. 8 is a view illustrating a state in which the controller PCB is coupled to the film (fabric) for the transparent LED display device through the soldering according to an embodiment. FIG. 9 is a view illustrating a state in which the controller PCB is coupled on the film (fabric) for the transparent LED display device according to an embodiment. According to an embodiment, the controller PCB may be disposed on an end of the second surface of the transparent heat-resistant optical PET film and then may be electrically connected to the line of the metal mesh pattern on the first surface through the soldering.

Referring back to FIG. 1, in operation S4000, the color LEDs may be mounted on the transparent heat-resistant optical PET film.

It should be noted that the color LEDs according to the present invention is configured to directly output an image signal seen to people, and the color LEDs are not used for a backlight of a display panel in the present invention.

FIG. 5 illustrates a portion of the transparent heat-resistant optical PET film according to an embodiment. Referring to FIG. 5, the wire having the grid-shaped metal mesh pattern may be formed on an LED film 4000, and the wire may have a width greater than 15 μm and less than 50 μm (e.g., about 30 μm). The color LEDs LN, LN+1, LN+2, LN+3, LN+4, and LN+5 may be mounted (SMT) on the LED film 4000. A distance (or pitch) between the color LEDs LN, LN+1, LN+2, LN+3, LN+4, and LN+5 may be greater than 5 mm and less than 40 mm (e.g., 10 mm). The current may be applied to the color LEDs LN, LN+1, LN+2, LN+3, LN+4, and LN+5 through the copper line formed in the form of the metal mesh pattern, and the color LEDs may emit light.

According to an embodiment, silver paste is applied to the tin plating layer formed in operation S2500 and heated to convert the silver paste into a liquid phase, and then, the color LED may be disposed. Then, the liquefied silver paste may be solidified again to connect the color LED to the film. According to an embodiment, the silver paste may be applied to the tin plating layer and heated to place the color LED on the silver paste and then converted from liquid silver to metallic silver so as to connect the color LED to the film.

Referring back to FIG. 1, in operation S5000, a switched mode power supply (SMPS) may be integrally coupled to the transparent heat-resistant optical PET film.

The SMPS may be a device that converts alternating current (AC) supplied from the outside into direct current (DC) so as to be converted into a voltage that meets conditions for various electronic devices to supply the voltage to the devices. That is, the SMPS may be a device for supplying the power to the transparent LED display device. In general, the SMPS is disposed outside the LED display device. The SMPS may deteriorate the overall aesthetics and visibility of the transparent LED display, and a separate bezel for placing the SMPS on the transparent LED display may exist to obscure the meaning as the transparent LED display and also deteriorate spatiality. In addition, since the power has to be supplied to each cell through a single SMPS, the power line has to be connected to each cell. In the case of display expansion, there are many power lines, and thus, there is a difficulty in scalability when installing the display.

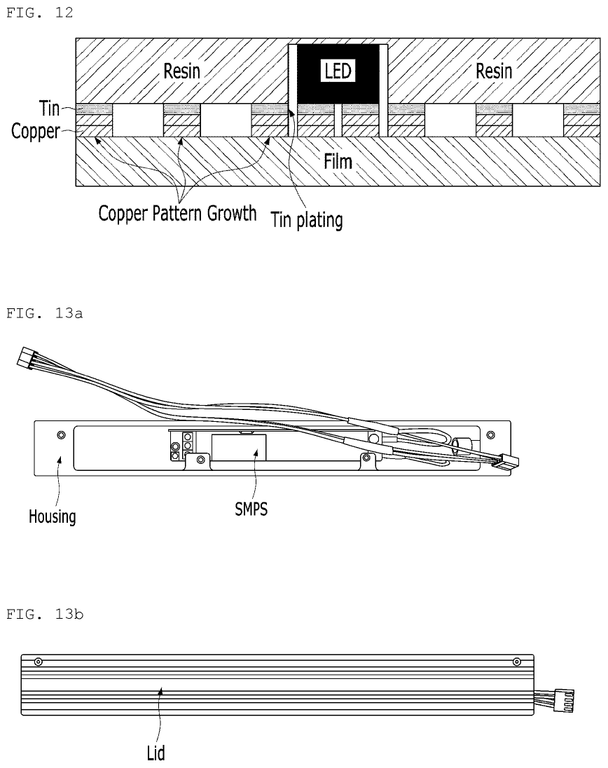

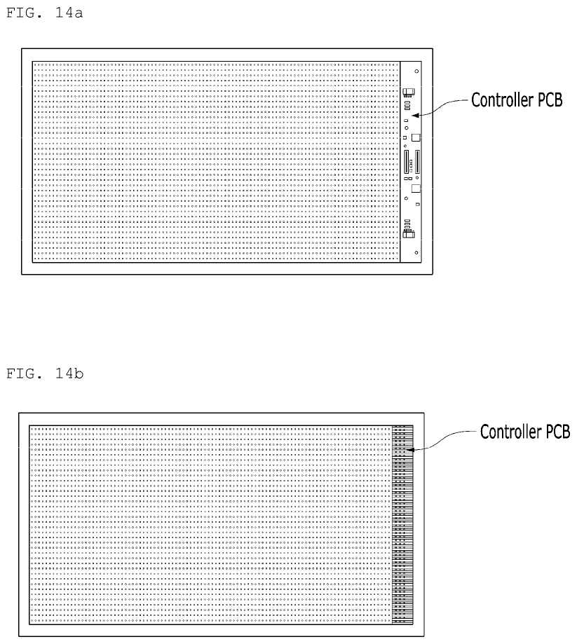

A power socket on the controller PCB substrate (coupled in operation S3000) on the second surface of both the surfaces of the transparent heat-resistant optical PET film may be connected to SMPS through the power line, and the housing including the SMPS may be assembled with the second surface of both the surfaces of the transparent heat-resistant optical PET film to integrally couple the SMPS to the transparent heat-resistant optical PET film. The SMPS may be disposed on a portion of a lid of the housing. FIG. 13a is a view illustrating a state in which the SMPS is embedded in the housing (under the lid), and FIG. 13b is a view illustrating a state in which the lid of the housing is seen in a state in which the housing of FIG. 13a is turned upside down. The SMPS may be disposed just below the lid of FIG. 13b. As a result, the housing may cover the controller PCB in the state in which the SMPS of the housing and the power socket of the controller PCB are connected to each other.

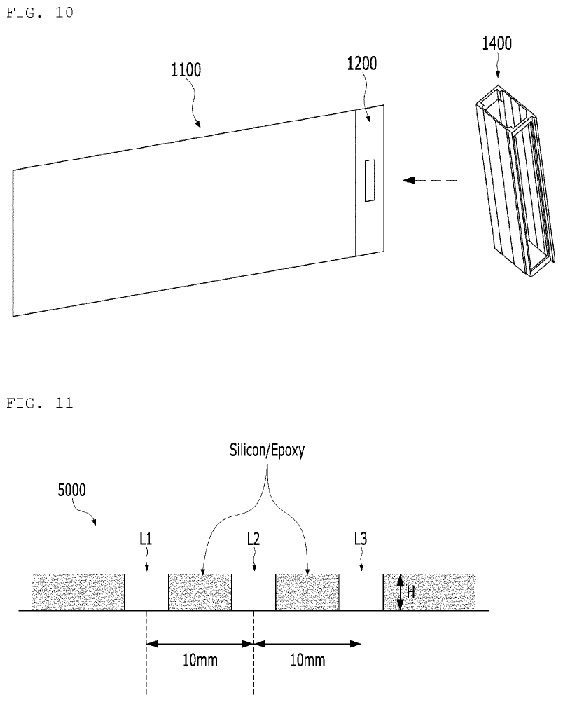

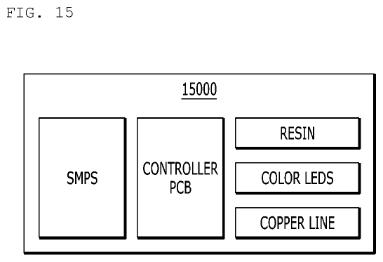

The controller PCB may include a power socket (VCC/GND) and a sub control unit (SCU) for supplying the power to the color LEDs of the transparent heat-resistant optical PET film. The SCU may receive data from an external micro control unit (MCU) to transmit data to the color LEDs. The color LEDs may emit light based on the received data. The SCU may be equipped with a communication module (LAN cable, Wi-Fi module, etc.) for communicating with the MCU. Referring to FIG. 10, the SMPS may be embedded in the housing 1400, the SMPS and the power socket on the controller PCB may be connected to each other through the power line, and the housing 1400 may be coupled to the controller PCB to integrally couple the SMPS to the transparent heat-resistant optical PET film. FIG. 14a is a view illustrating a first surface of a front surface or both surfaces of the transparent heat-resistant optical PET film, and FIG. 14b is a view illustrating a second surface of a rear surface or both the surfaces of the transparent heat-resistant optical PET film. The color LEDs may emit light in a forward direction, and the controller PCB and the PCB including the SMPS may be integrally coupled to each other in a backward direction.

Referring back to FIG. 1, in operation S6000, the transparent heat-resistant optical PET film may be by surface-treated using an adhesive material to compensate for a stepped portion caused by a difference in height between the color LEDs and the film surface or to form an adhesion layer for attaching the transparent heat-resistant optical PET film to another position.

According to an embodiment, a silicone or epoxy material may be surface-treated on the transparent heat-resistant optical PET film to compensate for the stepped portion caused due to the height of the color LEDs. Referring to FIG. 11, the color LEDs L1, L2, and L3 may be mounted on a portion of the LED film 5000, and the surface treatment using the silicone or epoxy material may be performed to compensate for the height H of the color LED. Thereafter, an optically clear adhesive (OCA) may be attached to one surface or both the surfaces of the LED film 5000, and thus, the LED film 5000 may be attached to a cover glass or attached to a specific installation position such as a window. However, when the OCA is used, it is difficult to perform the attachment and detachment, and thus, cracks may occur in the metal mesh line of the transparent LED display during the attachment and detachment, and the transparent LED display may be exposed to air except for a space in which the OCA is attached. As a result, the metal mesh line may be oxidized by oxygen and moisture in the air.

According to an embodiment, a resin may be used as an adhesive material. Since the resin is applied to the transparent heat-resistant optical PET film, when installing or attaching the corresponding transparent LED display to a wall or surface, water may be injected (sprayed) onto the surface to be installed or the transparent heat-resistant optical PET film (resin layer) to attach the transparent LED display device to a placed to be easily installed without a separate adhesive. According to an embodiment, since the resin is applied to all the surfaces (including the LEDs) of the transparent heat-resistant optical PET film, the transparent LED display device (particularly, the color LEDs) may be protected from the temperature and humidity, and the product may increase in lifespan. In addition, the attachment and detachment may be easier than those of the product using the OCA bonding technology, and it may have an excellent effect in waterproofing the display surface.

FIG. 12 is a cross-sectional view illustrating the transparent LED display device manufactured by the manufacturing method of FIG. 1 according to an embodiment. The first copper layer formed through the sputtering method and the second copper layer formed through the electroless chemical copper plating process may be formed on the film, and the tin plating layer (Tin) may be formed on the second copper layer. It is seen that the color LED is formed on the tin plating layer, and the resin layer is formed over the entire area of the film by including the upper end of the color LED.

FIG. 15 is a block diagram illustrating the transparent LED display device according to an embodiment.

A transparent display LED device 15000 may be manufactured by the manufacturing method disclosed with reference to FIG. 1, but is not limited thereto. The transparent LED display device 15000 may be attached to the wall or surface.

Referring to FIG. 15, the transparent LED display device 15000 may include a copper line formed in the form of a metal mesh pattern on a first surface of both surfaces (first surface and second surface) of a transparent heat-resistant optical PET film, color LEDs mounted on the first surface of both the surfaces of the transparent heat-resistant optical PET film, a resin applied to the first surface, a controller PCB configured to control an on/off state of the color LEDs or applied current and disposed on the second surface, and a housing including an SMPS for supplying power to the transparent LED display device 15000.

According to an embodiment, the copper line may be formed by operations S1000 and S2000 of FIG. 1. Water may be applied to the resin to adhere to the wall or surface. The resin may be applied to the first surface and may also be applied to the color LEDs.

The line of the controller PCB placed on the second surface of both the surfaces of the transparent heat-resistant optical PET film and the line of the metal mesh pattern of the first surface may be soldered through the holes penetrated in the transparent heat-resistant optical PET film to electrically connect the controller PCB to the line of the metal mesh pattern.

The housing may be integrally coupled to the second surface of the transparent heat-resistant optical PET film, and thus, the SMPS included in the housing and the power socket of the controller PCB on the transparent heat-resistant optical PET film may be connected through the power line.

The above-described one transparent heat-resistant optical PET film may be provided in plurality to implement a large transparent electric signboard or a digital signage system.

The descriptions are intended to provide the exemplary configurations and operations for implementing the present invention. The technical spirit of the present invention will include not only the embodiments described above, but also implementations that can be obtained by simply changing or modifying the above embodiments. In addition, the technical spirit of the present invention will include implementations that can be achieved by easily changing or modifying the embodiments described above in the future.

1. A method for manufacturing a transparent LED display device, the method comprising:
forming a copper layer on a transparent heat-resistant optical PET film;
forming a line having a grid-shaped metal mesh pattern on a first surface of both surfaces of a transparent heat-resistant optical PET by using a wet etching method on the transparent heat-resistant optical PET film;
plating tin on the line;
punching a hole in the transparent heat-resistant optical PET film and soldering a line of a controller PCB placed on a second surface of both the surfaces of the transparent heat-resistant optical PET and the line of the metal mesh pattern on the first surface to electrically connect the controller PCB to the line of the metal mesh pattern;
mounting color LEDs on the first surface of the transparent heat-resistant optical PET film;
connecting a power socket on the controller PCB to an SMPS through a power line and assembling a housing, in which the SMPS is embedded, with the second surface of the transparent heat-resistant optical PET film to integrally couple the SMPS to the transparent heat-resistant optical PET film; and
applying a resin to the first surface of the transparent heat-resistant optical PET film,
wherein the forming of the copper layer comprises forming a first copper layer on the transparent heat-resistant optical PET film by applying the sputtering method and forming a second copper layer on the first copper layer by applying an electroless chemical copper plating process.

2. The method of claim 1, wherein the first copper layer has a height of 1 μm, and the second copper layer has a height of 35 μm.

3. The method of claim 1, further comprising injecting water to a surface, on which the transparent heat-resistant optical PET film is attached, or the resin to attach the transparent heat-resistant optical PET film to the surface.

4. A transparent LED display device manufactured by the method for manufacturing the transparent heat-resistant optical PET film of claim 1.

5. A transparent LED display device being attachable to a wall or surface, the transparent LED display device comprising:
a copper line formed into a shape of a metal mesh pattern on a transparent heat-resistant optical PET film;
color LEDs mounted on a first surface of both surfaces of the transparent heat-resistant optical PET film; and
a resin applied to the first surface,
wherein water is applied to the resin so as to be attached to the wall or surface.

6. The transparent LED display device of claim 5, further comprising:
a controller PCB configured to control an on/off state of the color LEDs or applied current; and
a housing comprising an SMPS configured to supply power to the transparent LED display device,
wherein a line of a controller PCB placed on a second surface of both the surfaces of the transparent heat-resistant optical PET film and a line of the metal mesh pattern on the first surface are soldered through a hole punched in the transparent heat-resistant optical PET film to electrically connect the controller PCB to the line of the metal mesh pattern, and
the housing is integrally coupled to the transparent heat-resistant optical PET film so that an SMPS provided in the housing and a power socket on the transparent heat-resistant optical PET film are connected to each other through a power line.
